(19) United States
(12) Patent Application Publication
(10) Pub. No.: US 2011/0204965 A1
(43) Pub. Date: Aug. 25, 2011

(54) Apparatus and Method Pertaining to Facilitating a Measurement with Respect to Field Effect Transistor

(75) Inventors: Cetin Kaya, Plano, TX (US); Michael Pate, Allen, TX (US)

(73) Assignee: TEXAS INSTRUMENTS INCORPORATED, Dallas, TX (US)

(21) Appl. No.: 12/710,682

(22) Filed: Feb. 23, 2010

(51) Int. Cl. G05F 3/02; H01L 29/78; G01R 19/00; H03H 11/24

(52) U.S. Cl. 327/543; 257/48; 324/76.11; 327/581; 257/E29.256

(57) ABSTRACT

These various embodiments pertain to an FET having a plurality of fingers as correspond to the FET's source and drain. A first conductive lead electrically couples to a given one of this plurality of fingers while a second conductive lead electrically couples as well to this same given finger. A measurement component connects to these first and second conductive leads to measure at least one electrical parameter (such as voltage). By one approach, the first and second conductive leads physically connect to opposing ends of the given finger. These teachings will also accommodate providing a control component that is responsive to the measurement component to facilitate automatically controlling at least one operating state of the FET as a function, at least in part, of the measured electrical parameter.

### TECHNICAL FIELD

This invention relates generally to field effect transistors.

### BACKGROUND

Field effect transistors are known in the art and are often referred to by the acronym “FET.” FET's are often formed using metal-oxide semiconductor fabrication techniques and these, in turn, are often referred to by the acronym “MOSFET.” MOSFET's, in fact, have become nearly ubiquitous as a modern active circuit element given their numerous benefits and operating characteristics.

This is not to say, however, that MOSFET's of traditional design are suitable for all applications. For example, application settings characterized by high frequency and high power signals (such as, by way of illustration, a cellular telephony base station amplifier) can be unsuitable for traditional MOSFET's. To meet such a need, lateral diffused MOSFET's (often denoted as “LDMOS field effect transistors”) are employed. Such devices typically employ source and drain terminals that each electrically couple to a plurality (often dozens or even hundreds) of electrically conductive fingers that are often interlaced with one another.

Typical LDMOS-FET's, however, are variable impedance devices. Consequently, if a short circuit occurs at an output, the current can increase dramatically. Such components therefore often include over-current protection. This typically requires monitoring current through the FET to detect when and if this current exceeds a predetermined threshold. Unfortunately, this typically involves accommodating relatively high-voltage (such as 5 volts or more) and this in turn requires the use of high-voltage components (for example, transistors that are rated at 5 volts or more). Though effective, these high-voltage components require considerable space within the device and also often exhibit slower speeds.

### BRIEF DESCRIPTION OF THE DRAWINGS

The above needs are at least partially met through provision of the apparatus and method pertaining to facilitating a measurement with respect to a field effect transistor described in the following detailed description, particularly when studied in conjunction with the drawings, wherein:

FIG. 1 comprises a flow diagram as configured in accordance with various embodiments of the invention; and

FIG. 2 comprises a block-diagram schematic view as configured in accordance with various embodiments of the invention.

Skilled artisans will appreciate that elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention. It will further be appreciated that certain actions and/or steps may be described or depicted in a particular order of occurrence while those skilled in the art will understand that such specificity with respect to sequence is not actually required. It will also be understood that the terms and expressions used herein have the ordinary technical meaning as is accorded to such terms and expressions by persons skilled in the technical field as set forth above except where different specific meanings have otherwise been set forth herein.

### SUMMARY

Generally speaking, these various embodiments pertain to a field effect transistor having a plurality of fingers. This plurality comprises, at the least, a plurality of source fingers and/or a plurality of drain fingers. A first conductive lead electrically couples to a given one of this plurality of fingers while a second conductive lead electrically couples as well to this same given finger. A measurement component connects to these first and second conductive leads to measure at least one electrical parameter.

By one approach, the first and second conductive leads physically connect to opposing ends of the given finger. The given finger can comprise either a source finger or a drain finger to accommodate a given application setting. By one approach the measured electrical parameter can comprise voltage. These teachings will also accommodate providing a control component that is responsive to the measurement component to facilitate automatically controlling at least one operating state of the FET as a function, at least in part, of the measured electrical parameter.

So configured, an over-current state can be quickly and readily detected. As these teachings rely upon what is inherently a low-voltage setting, however, these teachings will readily accommodate using only low-voltage components. By avoiding the use of high-voltage components in these regards, these teachings greatly reduce on-chip space requirements as well as corresponding response times. Those skilled in the art will appreciate that these teachings are highly flexible in practice and will accommodate a wide variety of application-setting variations. These teachings are also easily implemented and are cost-effective in practice.

### DETAILED DESCRIPTION

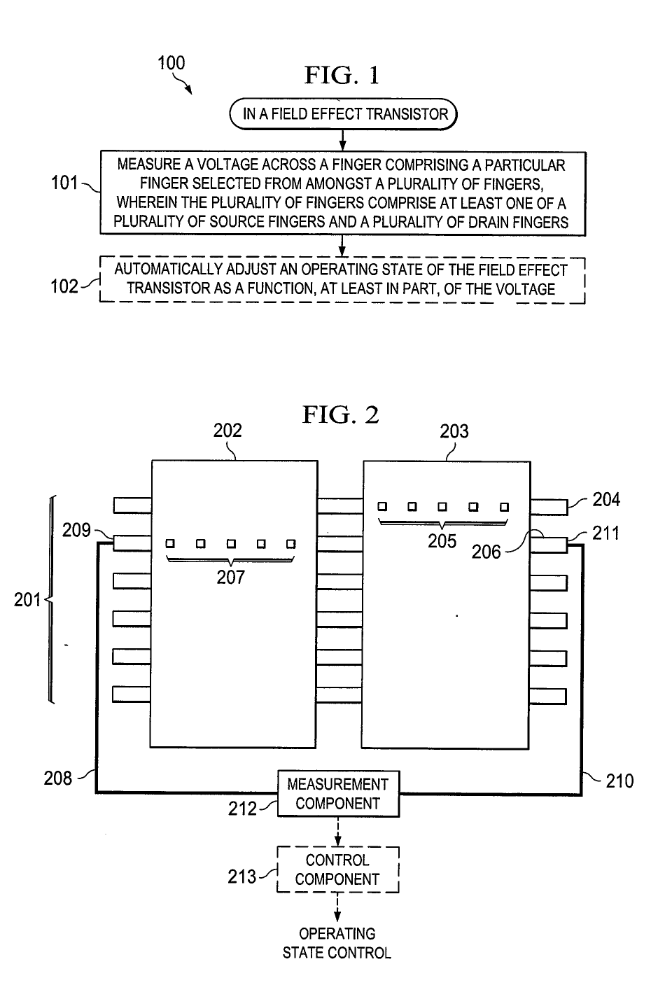

These and other benefits may become clearer upon making a thorough review and study of the following detailed description. Referring now to the drawings, and in particular to FIG. 1, an illustrative process 100 that is compatible with many of these teachings will now be presented.

As illustrated, this process 100 is practiced with respect to a field effect transistor. For purposes of this description and not by way of limitation, this field effect transistor will be presumed to comprise an LDMOS field effect transistor. Accordingly, and referring now momentarily to FIG. 2, this LDMOS field effect transistor comprises a plurality of fingers 201 that are comprised of electrically-conductive material and that are disposed generally parallel to one another. This plurality of fingers 201 underlies two terminal surfaces, these comprising a source 202 and a drain 203 (these terminal surfaces being comprised, for example, of copper).

The fingers 201 electrically connect to the terminals 202 and 203 by use of electrically-conductive vias. For example, the uppermost finger 204 electrically connects by way of a first plurality of such vias 205 to the drain terminal 203 and the next adjacent finger 206 similarly electrically connects by way of a second plurality of such vias 207 to the source terminal 202. (The remaining fingers 201 similarly connect to these terminals in an alternating, interleaved manner such that every other finger 201 electrically connects to the source 202 and the remaining fingers 201 electrically connect to the drain 203. These other connections are similarly realized by corresponding vias, which vias are not shown here for the sake of clarity and simplicity.)

Those skilled in the art will understand that a typical LDMOS field effect transistor will typical have a considerably greater number of fingers. Only six such fingers are shown here for the sake of clarity and simplicity and it will be appreciated that these teachings are readily applied in conjunction with any number of such fingers. Those skilled in the art will also know that such fingers can be comprised of a single metal, such as aluminum, or can be comprised of two or more layers of differentiated metal (such as aluminum and copper) in order to increase the current-handling capability of the component.

Returning now to FIG. 1, this process 100 provides the step 101 of measuring a voltage across a finger as selected from amongst the plurality of fingers. This step will accommodate selecting this finger from amongst a plurality of source fingers as described above or a plurality of drain fingers, as desired.

By one approach, this step 101 can comprise measuring voltage across the selected finger from one tip of the finger to the opposing tip. For example, and referring again to FIG. 2, a first conductive lead 208 (formed, for example, of a copper trace) can be coupled to one tip 209 of a selected source finger 206 and a second conductive lead 210 can be similarly coupled to the opposing tip 211 of this same source finger 206. Both of these conductive leads 208 and 210 connect in this illustrative example to a measurement component 212 that serves to measure the electrical parameter of interest (in this example, the voltage across this particular source finger 206 from one tip to another).

Those skilled in the art will recognize that the aforementioned conductive leads 208 and 210 need not necessarily attach to the tip of the finger. Instead, it would be possible to make this point of attachment elsewhere on the finger if desired. Generally speaking, however, as the difference in potential across the finger is relatively small (for example, around 50 millivolts), the task of making this measurement and achieving a useful result is made easier by providing the greatest distance possible between these two points of attachment.

Those skilled in the art will appreciate that, as noted above, the voltage across a given finger will be quite small. This, in turn, permits the measurement component 212 to be realized without relying upon a single high-voltage active device (i.e., transistors designed to operate at greater than five volts). Instead, the measurement component 212 can be comprised of low-voltage devices (such as transistors that are designed to operate using 1.8 volts or 3.3 volts). Low-voltage devices, of course, have a smaller fabrication footprint than high-voltage devices. Accordingly, the measurement component 212 can be considerably smaller than would otherwise be expected in the prior art. This can lead to both space savings as well as operational-speed increases.

Those skilled in the art will also appreciate that these teachings avoid the use of an extra resistive element placed in series with the FET itself in order to detect an over-current state. Instead, the illustrated approach leverages already-existing structure within the FET itself. The skilled artisan will again appreciate that additional space savings are a likely result.

Referring now to both FIGS. 1 and 2, this process 100 will further accommodate, if desired, the optional step 102 of automatically adjusting an operating state of the field effect transistor as a function, at least in part, of the measured parameter. By one approach, for example, a control component 213 receives information from the aforementioned measurement component 212 regarding the measured parameter and provides a corresponding operating state control output signal. This received information can comprise, for example, the measurement itself (such as the measured voltage across the monitored finger). As another example, this information can comprise the arithmetic results of a comparison of this measurement with a pre-determined threshold. As yet another example, this information can comprise an indication of whether the measurement exceeds such a threshold.

Those skilled in the art will recognize that there are various such measuring components and control components known in the art, with other approaches likely being introduced in the future. As these teachings are not overly sensitive to any particular selections in these regards, for the sake of brevity and the preservation of clarity, further elaboration in these regards will not be presented here.

So configured, these teachings provide an efficient, low-cost approach to monitoring an FET for an over-current state. These teachings will readily accommodate leveraging the existing architecture of the device without requiring an additional in-series resistive element. These teachings will also permit such a state to be monitored in the absence of high-voltage active components. Accordingly, these teachings require less space in a typical integrated circuit setting and are typically capable of faster operation.

Those skilled in the art will recognize that a wide variety of modifications, alterations, and combinations can be made with respect to the above described embodiments without departing from the spirit and scope of the invention, and that such modifications, alterations, and combinations are to be viewed as being within the ambit of the inventive concept. As but one example in these regards, these teachings will accommodate also measuring the voltage across one or more additional fingers and taking all of these measurements into account when determining whether an over-current situation is occurring.

1. An apparatus comprising:
a field effect transistor (FET) having a plurality of fingers that are generally in parallel to one another and that are each formed of a conductive material, wherein the plurality of fingers include a set of source fingers and a set of drain fingers that are interleaved;
a first conductive lead electrically coupled to a a first end of a first finger of the plurality of fingers;
a second conductive lead electrically coupled to a second end of the first finger; and
a measurement circuit connected to the first and second conductive leads to measure a voltage across the first finger, wherein the measurement circuit operates at a low voltage.

2. The apparatus of claim 1, wherein the FET comprises a lateral diffused metal oxide semiconductor (LDMOS) FET.

3-6. (canceled)

7. The apparatus of claim 1, wherein the apparatus further comprises a control component responsive to the measurement component to automatically control at least one operating state of the FET as a function, at least in part, of the voltage across the first finger.

8-18. (canceled)

19. The appparatus of claim 7, wherein the apparatus further comprises:
a source terminal that is coupled to each source finger; and
a drain terminal that is coupled to each drain finger, wherein the drain terminal and the source terminal are formed, at least in part, of copper.

20. The apparatus of claim 19, wherein low voltage is 3.3V or 1.8V.

21. The apparatus of claim 20, wherein the apparatus further comprises:
a first set of conductive vias formed between the set of source fingers and the source terminal; and
a second set of conductive vias formed between the set of drain fingers and the drain terminal.
